(19) United States
(12) Patent Application Publication
(10) Pub. No.: US 2020/0168402 A1
(43) Pub. Date: May 28, 2020

(54) MICROELECTRONIC DEVICES DESIGNED WITH PACKAGE INTEGRATED VARIABLE CAPACITORS HAVING PIEZOELECTRIC ACTUATION

(71) Applicant: Intel Corporation, Santa Clara, CA (US)

(72) Inventors: Feras EID, Chandler, AZ (US); Aleksandar ALEKSOV, Chandler, AZ (US); Georgios C. DOGIAMIS, Chandler, AZ (US); Thomas L. SOUNART, Chandler, AZ (US); Johanna M. SWAN, Scottsdale, AZ (US)

(21) Appl. No.: 16/605,968

(22) PCT Filed: Jun. 27, 2017
(86) PCT No.: PCT/US2017/039597

§ 371 Date: Oct. 17, 2019

(51) Int. Cl. H01G 5/16; H01G 5/14; H01L 23/00

(52) U.S. Cl. CPC H01G 5/16; H01L 2924/19041; H01L 24/26; H01G 5/14

(57) ABSTRACT

Embodiments of the invention include a microelectronic device that includes a plurality of organic dielectric layers and a piezoelectrically actuated tunable capacitor having a variable capacitance formed in-situ with at least one organic dielectric layer of the plurality of organic dielectric layers. A piezoelectric actuator of the tunable capacitor includes first and second conductive electrodes and a piezoelectric layer that is positioned between the first and second conductive electrodes.

### FIELD OF THE INVENTION

Embodiments of the present invention relate generally to the manufacture of semiconductor devices. In particular, embodiments of the present invention relate to microelectronic devices that are designed with package integrated variable capacitors having piezoelectric actuation.

### BACKGROUND OF THE INVENTION

Tunable RF circuits are desired in wireless communication systems since these tunable RF circuits enable multiband and multimode communications using the same hardware components. The tunable RF circuits provide significant form factor and component count reduction compared to using multiple, non-tunable components to address each desired frequency or band. Current tunable circuits utilize a capacitor bank on silicon, diodes and on-die switches that allow setting a desired capacitance by connecting one or more switches to the capacitor bank. However, this approach consumes valuable area on expensive silicon (Si) wafers. Another approach consists of using Si-based microelectromechanical systems (MEMS) RF switches to create variable capacitors which are then attached as a discrete package to the system. This approach also suffers from the cost of Si MEMS manufacturing as well as the need to purchase and assemble a discrete part to the communication system.

### BRIEF DESCRIPTION OF THE DRAWINGS

FIG. 1 illustrates a microelectronic device having package integrated tunable capacitor with variable capacitance and a substrate in accordance with one embodiment.

FIG. 2A illustrates a top view of a microelectronic device having a package substrate with a package integrated piezoelectrically actuated tunable capacitor in accordance with one embodiment.

FIG. 2B illustrates a cross-sectional view BB′ of a microelectronic device having a package substrate with a package integrated piezoelectrically actuated tunable capacitor in accordance with one embodiment.

FIG. 3A illustrates a cross-sectional view of a microelectronic device having a package substrate with a package integrated piezoelectrically actuated tunable capacitor in an unactuated state in accordance with one embodiment.

FIG. 3B illustrates a cross-sectional view of a microelectronic device having a package substrate with a package integrated piezoelectrically actuated tunable capacitor in an actuated state in accordance with one embodiment.

FIG. 4A illustrates a top view of a microelectronic device having a package substrate with a package integrated piezoelectrically actuated tunable capacitor in accordance with one embodiment.

FIG. 4B illustrates a cross-sectional view CC′ of a microelectronic device having a package substrate with a package integrated piezoelectrically actuated tunable capacitor in accordance with one embodiment.

FIG. 5A illustrates a cross-sectional view of a microelectronic device having a package substrate with a package integrated piezoelectrically actuated tunable capacitor in an unactuated state in accordance with one embodiment.

FIG. 5B illustrates a cross-sectional view of a microelectronic device having a package substrate with a package integrated piezoelectrically actuated tunable capacitor in an actuated state in accordance with one embodiment.

FIG. 6A illustrates a top view of a microelectronic device having a package substrate with a package integrated piezoelectrically actuated tunable capacitor in an unactuated state in accordance with one embodiment.

FIG. 6B illustrates a top view of a microelectronic device having a package substrate with a package integrated piezoelectrically actuated tunable capacitor in an actuated state in accordance with one embodiment.

FIG. 7 illustrates a cross-sectional view of a microelectronic device having a package substrate with a package integrated piezoelectrically actuated tunable capacitor in accordance with an alternative embodiment.

FIG. 8 illustrates a computing device 1000 in accordance with one embodiment.

### DETAILED DESCRIPTION OF THE INVENTION

Described herein are microelectronic devices that are designed as package integrated variable capacitors having piezoelectric actuation. In the following description, various aspects of the illustrative implementations will be described using terms commonly employed by those skilled in the art to convey the substance of their work to others skilled in the art. However, it will be apparent to those skilled in the art that embodiments of the present invention may be practiced with only some of the described aspects. For purposes of explanation, specific numbers, materials and configurations are set forth in order to provide a thorough understanding of the illustrative implementations. However, it will be apparent to one skilled in the art that embodiments of the present invention may be practiced without the specific details. In other instances, well-known features are omitted or simplified in order to not obscure the illustrative implementations.

Various operations will be described as multiple discrete operations, in turn, in a manner that is most helpful in understanding embodiments of the present invention, however, the order of description should not be construed to imply that these operations are necessarily order dependent. In particular, these operations need not be performed in the order of presentation.

Currently, the need for tunable communication systems has become even more apparent with the co-existence of several communication protocols on a single device (e.g., BlueTooth, WiFi, 3G, 4G/LTE, 5G) and amplified by the fact that different geographic locations (e.g., EU, USA, China, Korea, Japan) have different communication band requirements. For example in today's telecommunication devices, more than 10×10 mm² on package/PCB area is consumed by filters and switches to enable the 10 or more different bands that are allocated. Introducing tunable elements in such area sensitive systems would be highly desirable. Moreover low cost fabrication techniques of those would be advantageous for their wide adoption.

The present design addresses the fabrication of tunable capacitors with variable capacitance within the semiconductor package substrate that is compatible with high volume package substrate fabrication technology. This present design is based on a demonstrated ability to deposit piezoelectric materials in the package substrate. The present design allows the fabrication of tunable capacitors having variable capacitance utilizing substrate manufacturing technology. The present design builds variable capacitors using panel-level organic substrate technology which is more cost effective than wafer-based silicon microfabrication. The capacitors are built directly as part of the substrate instead of building them on die or assembling them as discrete components. In comparison to traditional un-tuned multiband systems, the present design enables much smaller form factor and a reduction in both component count and costs.

These capacitors include actuators containing stacks of piezoelectric materials (e.g., lead zirconate titanate (PZT), sodium potassium niobate (KNN), zinc oxide (ZnO), or other materials) disposed between metal electrodes. The capacitance between two members (e.g., plates, fingers, beams, etc.) separated by a gap d and having an overlapping area A is proportional to A/d. In this present design, a package integrated piezoelectric actuator is connected to one or both members of a capacitor. When a voltage is applied to the piezoelectric stack, the actuator deforms causing the attached members to move. This causes a change in either area A or gap d and hence changes the capacitance. A variable capacitor having a variable capacitance is realized by controlling the voltage applied to the piezoelectric stack.

The present design results in package-integrated tunable capacitors having variable capacitance, thus enabling reconfigurable systems. Since the capacitors are embedded within the existing package layers, this present design leads to systems with reduced form-factors, i.e., reduced area and thickness. This present design can be manufactured as part of the substrate fabrication process and as such could reduce or even eliminate the need for discrete capacitor components. It is therefore a high volume manufacturable solution, which may reduce the cost of electronic systems in package while enabling tunability such as tunable RF Filters, phased arrays, etc.

The present design includes a variable capacitor that is fabricated directly in-situ on a low-temperature organic substrate or in a low-temperature organic substrate to form a package-integrated capacitor with low Z-height and no required assembly. The capacitor fabrication can also be integrated into the existing package substrate layers, thus freeing up land-side area for input output (JO) and power bumps, and eliminating Z-height entirely for the integrated capacitor.

The present design utilizes thin films of piezoelectric material (e.g., lead zirconate titanate (PZT), sodium potassium niobate (KNN), zinc oxide (ZnO), etc.), that is deposited on one or more of the layers in an organic package substrate to act as part of the actuator of a tunable substrate-integrated capacitor. The deposition is carried out at substrate-compatible temperatures, using, for example, pulsed laser anneal to crystallize the piezoelectric film while keeping the substrate at low temperatures (e.g., less than 215 degrees C.) to prevent damaging the organic layers. The piezoelectric thin film is sandwiched between two electrode layers that are deposited and patterned using substrate manufacturing techniques to complete the piezoelectric actuator stack.

Conventional discrete capacitors occupy large areas of the land-side of the package. In the present design, the capacitors can be fabricated within the layers of the substrate, therefore reducing or eliminating the discrete power-delivery capacitors on the land-side, providing more area for lands/bumps, and ultimately reducing the package x-y form-factor.

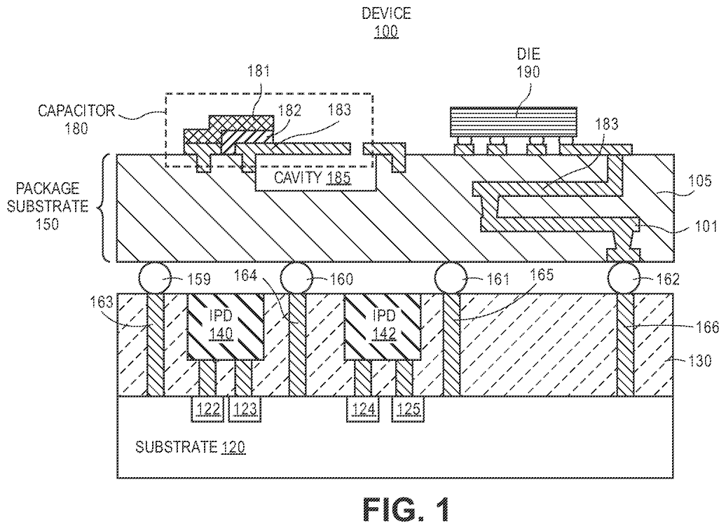

FIG. 1 illustrates a microelectronic device having package integrated tunable capacitor with variable capacitance and a substrate in accordance with one embodiment. The microelectronic device 100 includes an optional substrate 120 and a package substrate 150 having tunable variable capacitors. The package substrate 150 includes integrated tunable capacitor 180, conductive layers (e.g., 101, 103), and dielectric material 105 (e.g., organic material, low temperature co-fired ceramic materials, liquid crystal polymers, etc.). The capacitor 180 includes a piezoelectric stack including conductive upper electrode 181 and lower electrode 183 and piezoelectric layer 182 that is disposed between the conductive electrodes. A cavity 185 is formed by selectively removing dielectric material 105.

The components 122-125 of the substrate 120 and IPDs (Integrated Passive Devices) 140 and 142 can communicate with components of the substrate 150 or other components not shown in FIG. 1 using connections 163-166 and solder balls 159-162. The IPDs may include any type of passives including inductors, transformers, capacitors, and resistors. In one example, capacitors on the IPD die may be used for power delivery. In another example, resistors on the same or a different IPD may be used for digital signal equalization. In another example, the substrate 120 is a printed circuit board.

The capacitor 180 can be created in-situ during substrate manufacturing as part of the build up layers of the substrate 150. The capacitor 180 can also be coupled to the die 190 or components of the substrate 120.

The present design utilizes package-integrated piezoelectric structures (e.g., 182) to act as actuators for RF tunable capacitors. The actuator stack includes piezoelectric material positioned between patterned metal electrodes. Applying a voltage to the electrodes causes the capacitive members attached to one or both of them to move. This causes a change in either area A or gap d of the capacitive members and hence changes the capacitance. A variable capacitor having a variable capacitance is realized by controlling the voltage applied to the piezoelectric stack.

In one example, typical tuning ranges are from 1-100%. Capacitor electrode sizes may range from 4 um² up to several hundreds of um² and may provide capacitance values ranging from hundreds of femtofarads (fF) to nanofarad (nF) values. Typical package layer thickness may range from 2 um to 50 um. Piezoelectric layer thicknesses may range from below 30 nanometers (nm) to 1 um. Metal electrode thicknesses may range from 1 um-15 um.

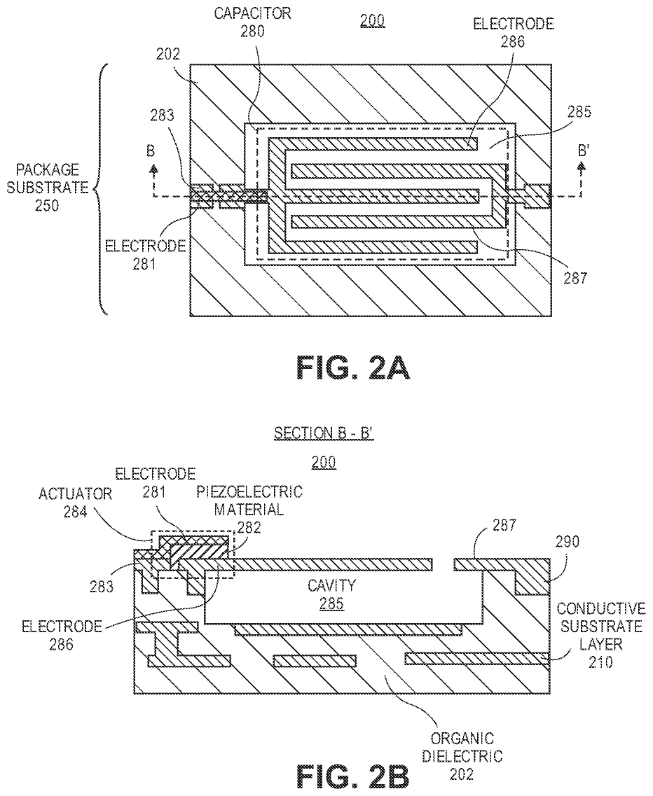

One architecture utilizes interdigitated members (e.g., fingers) as illustrated in FIG. 2A and out-of-plane actuation. FIG. 2A illustrates a top view of a microelectronic device having a package substrate with an integrated piezoelectrically actuated variable capacitor in accordance with one embodiment. The microelectronic device 200 includes a package substrate 250 having a piezoelectrically actuated tunable capacitor 280, dielectric material 202 (e.g., organic material, low temperature co-fired ceramic materials, liquid crystal polymers, etc.) that includes organic layers, and different levels of conductive layers and connections. The capacitor 280 includes conductive electrodes 281 and 286 of the piezoelectric actuator 284, a piezoelectric layer 282, and a conductive layer 287 as illustrated in FIGS. 2A and 2B. The capacitor 280 is formed in the organic package substrate 250 and electrically routed with the standard conductive layers and connections in the package substrate. The conductive electrode 286 includes a first set of fingers (connected members). A conductive layer 287 includes a second set of fingers (connected members) and is formed in an interdigitated configuration with the first set of fingers 286.

FIG. 2B illustrates a cross-sectional view BB′ of a microelectronic device having a package substrate with a package integrated piezoelectric capacitor in accordance with one embodiment. The capacitor 280 includes conductive electrodes 281 and 286 of the piezoelectric actuator 284 and a piezoelectric layer 282. The capacitor 280 is formed in the organic package substrate 250 and electrically routed with the standard conductive layers 210 and connections 283 and 290 in the package substrate. The conductive electrode 286 includes a first set of fingers (connected members). A second set of fingers 287 (connected members) is formed in an interdigitated configuration with the first set of fingers 286. The connections 283 and 290 (e.g., anchors 283 and 290) provide mechanical support for the electrodes and sets of fingers.

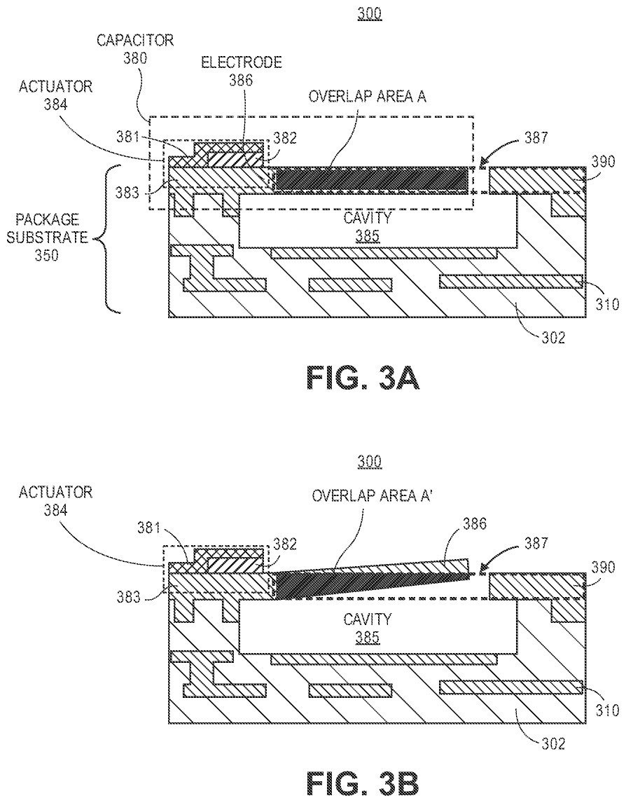

FIG. 3A illustrates a cross-sectional view of a microelectronic device having a package substrate with an integrated piezoelectrically actuated tunable capacitor in an unactuated state in accordance with one embodiment. The microelectronic device 300 includes a package substrate 350 having a piezoelectrically actuated tunable capacitor 380, dielectric material 302 (e.g., organic material, low temperature co-fired ceramic materials, liquid crystal polymers, etc.) that includes organic layers, and different levels of conductive layers and connections. The capacitor 380 includes conductive electrodes 381 and 386 of the piezoelectric actuator 384, a piezoelectric layer 382, and a conductive layer 387. The piezoelectric layer 382 is positioned between the electrodes 381 and 386 of the actuator 384. The capacitor 380 is formed in the organic package substrate 350 and electrically routed with the standard conductive layers and connections in the package substrate. The conductive electrode 386 includes a first region having a first set of fingers (connected members). The conductive layer 387 includes a second region having a second set of fingers (connected members) and is formed in an interdigitated configuration with the first set of fingers 386.

FIG. 3B illustrates a cross-sectional view of a microelectronic device having a package substrate with an integrated piezoelectrically actuated tunable capacitor in an actuated state in accordance with one embodiment. The capacitor 380 is formed in the organic package substrate 350 and electrically routed with the standard conductive layers 310 and connections in the package substrate. The conductive electrode 386 includes a first region having a first set of fingers (connected members). The connections 383 and 390 (e.g., anchors 383 and 390) provide mechanical support for the electrodes and sets of fingers. In this architecture of FIGS. 3A and 3B, when a voltage is applied across the piezo stack, the first region of the electrode 386 moves in the vertical direction (e.g., up or down in the section view as shown in FIG. 3B). This causes the overlap region (e.g., overlap area) between the first and second regions (e.g., first and second set of fingers) to change between overlap region A and A′ and hence the capacitance to change. A variable capacitor is realized by controlling the voltage applied to the electrodes of the actuator 384 (e.g., piezo stack).

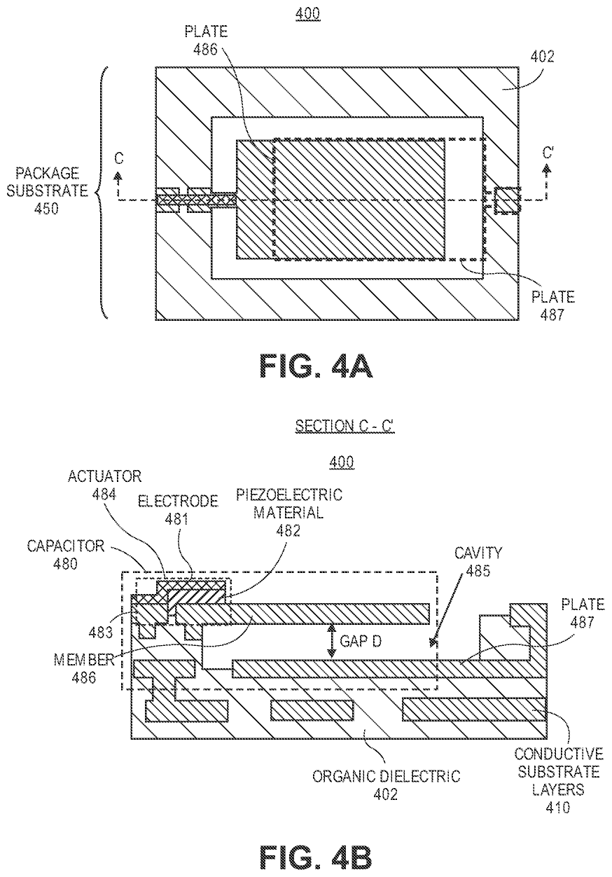

FIG. 4A illustrates a top view of a microelectronic device having a package substrate with an integrated piezoelectrically actuated tunable capacitor in accordance with one embodiment. The microelectronic device 400 includes a package substrate 450 having a piezoelectrically actuated tunable capacitor 480 (as outlined in FIG. 4B), dielectric material 402 (e.g., organic material, low temperature co-fired ceramic materials, liquid crystal polymers, etc.) that includes organic layers, and different levels of conductive layers and connections. The capacitor 480 includes conductive electrodes 481 and 486 of an actuator 484, a piezoelectric layer 482, and a conductive layer 487. The capacitor 480 is formed in the organic package substrate 450 and electrically routed with the standard conductive layers and connections in the package substrate. The conductive electrode 486 (or member 486) is shaped like a plate in FIGS. 4A and 4B. A conductive layer 487 (or member 487) is shaped like a plate in FIGS. 4A and 4B.

FIG. 4B illustrates a cross-sectional view CC′ of a microelectronic device having a package substrate with an integrated piezoelectrically actuated tunable capacitor 480 in accordance with one embodiment. The connection 483 (e.g., anchor 483) provides mechanical support for one of the electrodes of the actuator 484. The members 486 and 487 are separated by a gap d of a cavity 485 in an unactuated state. This architecture utilizes a parallel plate capacitor and out of plane actuation. In this architecture, the capacitor 480 includes two members (e.g., plates) separated by a gap d in the vertical direction. The members can be beams, cantilevers, or membranes of any shape (e.g., rectangular, square, circle, triangle, etc) or combinations of those shapes. The members can be anchored on one or both sides.

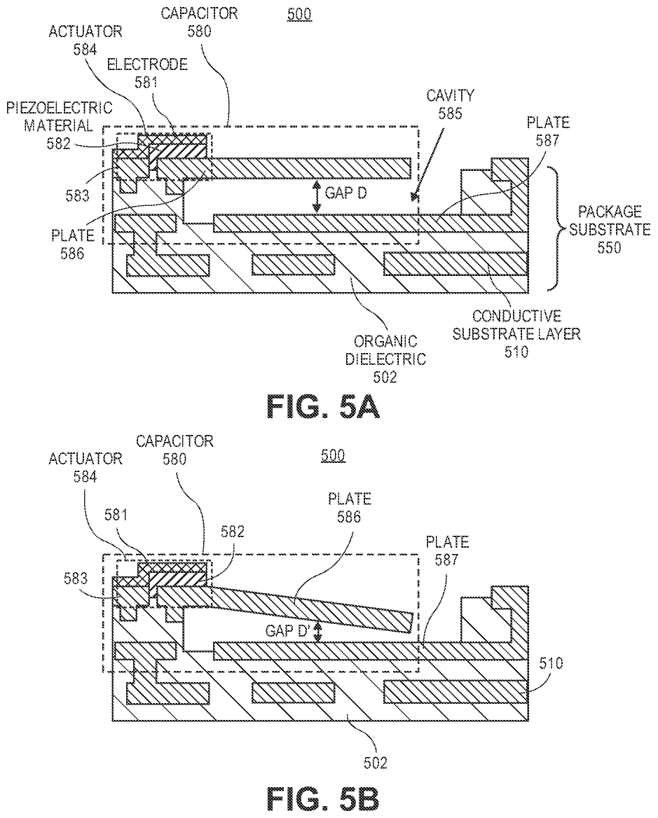

FIG. 5A illustrates a cross-sectional view of a microelectronic device having a package substrate with an integrated piezoelectrically actuated tunable capacitor in an unactuated state in accordance with one embodiment. The microelectronic device 500 includes a package substrate 550 having piezoelectrically actuated tunable capacitor 580, dielectric material 502 (e.g., organic material, low temperature co-fired ceramic materials, liquid crystal polymers, etc.) that includes organic layers, and different levels of conductive layers and connections. The capacitor 580 includes conductive electrodes 581 and 586 of the piezoelectric actuator 584, a piezoelectric layer 582, and a conductive layer 587.

The capacitor 580 is formed in the organic package substrate 550 and electrically routed with the standard conductive layers and connections in the package substrate. The conductive electrode 586 (e.g., member 586) is shaped like a plate in FIGS. 5A and 5B. A conductive layer 587 (e.g., member 588) is shaped like a plate in FIGS. 5A and 5B. The members can be beams, cantilevers, or membranes of any shape (e.g., rectangular, square, circle, triangle, etc) or combinations of those shapes. The members can be anchored on one or both sides.

FIG. 5B illustrates a cross-sectional view of a microelectronic device having a package substrate with an integrated piezoelectrically actuated tunable capacitor in an actuated state in accordance with one embodiment. The capacitor 580 includes conductive electrodes 581 and 586 of the piezoelectric actuator 584 and a piezoelectric layer 582. The connection 583 (e.g., anchor 583) provides mechanical support for one of the electrodes. In this architecture of FIGS. 5A and 5B, when a voltage is applied across the piezo stack, one or both of the members 586 and 587 move causing a gap d in an unactuated state to change into a gap d′ in an actuated state in a cavity 585. This causes the capacitance to change. A variable capacitor is realized by controlling the voltage applied to the piezo stack.

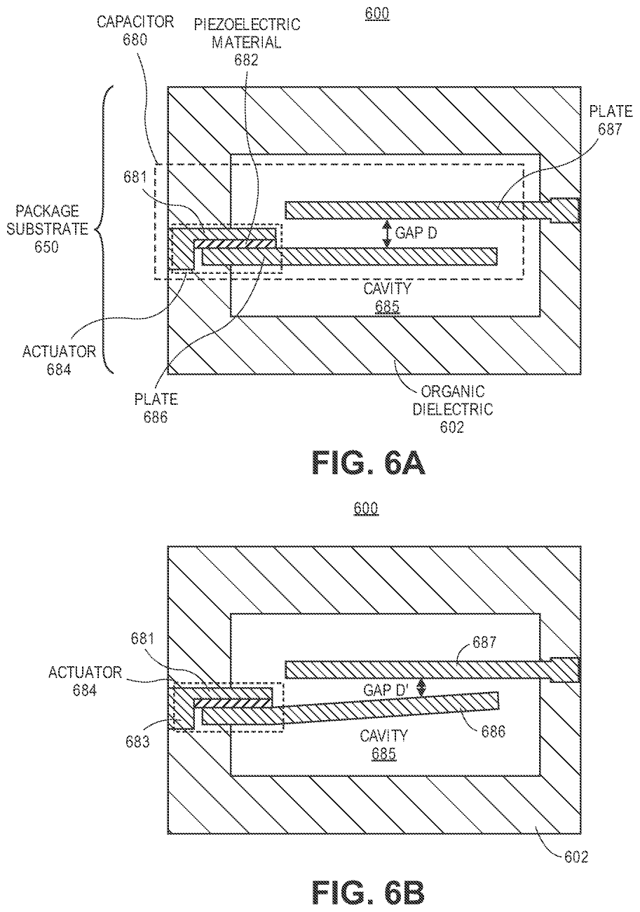

FIG. 6A illustrates a top view of a microelectronic device having a package substrate with an integrated piezoelectrically actuated tunable capacitor in an unactuated state in accordance with one embodiment. The microelectronic device 600 includes a package substrate 650 having a piezoelectrically actuated tunable capacitor 680, dielectric material 602 (e.g., organic material, low temperature co-fired ceramic materials, liquid crystal polymers, etc.) that includes organic layers, and different levels of conductive layers and connections. The capacitor 680 includes conductive electrodes 681 and 686 of the piezoelectric actuator 684, a piezoelectric layer 682, and a conductive layer 687. The capacitor 680 is formed in the organic package substrate 650 and electrically routed with the standard conductive layers and connections in the package substrate. The conductive electrode 686 (e.g., member 686) is shaped like a plate in FIGS. 6A and 6B. A conductive layer 687 (e.g., member 687) is shaped like a plate in FIGS. 6A and 6B. The members can be beams, cantilevers, or membranes of any shape (e.g., rectangular, square, circle, triangle, etc) or combinations of those shapes. The members can be anchored on one or both sides.

FIG. 6B illustrates a top view of a microelectronic device having a package substrate with an integrated piezoelectrically actuated tunable capacitor in an actuated state in accordance with one embodiment. The connection 683 (e.g., anchor 683) provides mechanical support for the one of the electrodes. This architecture of FIGS. 6A and 6B utilizes a parallel plate configuration with in-plane actuation. The piezo stack is deposited in the plane of the members (e.g., plates). When a voltage is applied across the piezo stack, one or both of the members 686 and 687 move in-plane causing a gap d in an unactuated state to change into a gap d′ in an actuated state in a cavity 685. This causes the capacitance to change. A variable capacitor is realized by controlling the voltage applied to the piezo stack. The members can be beams, cantilevers, or membranes of any shape. The members can be anchored on one or both sides.

In the architectures discussed herein, even though only one of the members (e.g., plates or finger sets) is shown connected to the piezo stack, a second piezo stack can also be deposited and attached to the second member (e.g., plate or finger set). This can enable a wider tuning range by allowing larger changes in the overlap area or gap.

In the architectures discussed herein, the capacitor members are patterned as part of the substrate conductive trace layers (e.g., using copper or other conductive material). Organic dielectric normally surrounds copper traces in packages/PCBs; however this organic material is removed around the members (e.g., plates or fingers) to allow movement (creating an air gap). The piezoelectric stacks are deposited and patterned such that they are mechanically coupled to one or both of the members. Each stack consists of a piezoelectric material such as lead zirconate titanate (PZT), sodium potassium niobate (KNN), zinc oxide (ZnO), or other materials sandwiched between conductive electrodes.

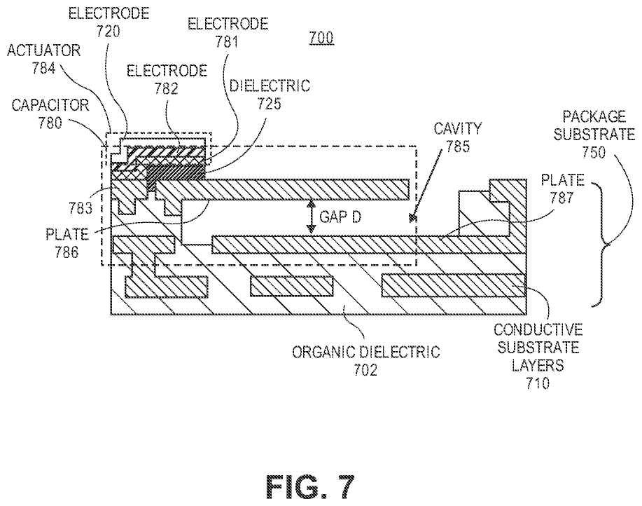

One of the capacitor members (e.g., plates or fingers) can be used as one of the electrodes for the piezoelectric actuator stack as shown in the figures discussed herein, or alternatively as illustrated in FIG. 7, a separate conductive material can be used for that first electrode after depositing an insulating layer to electrically decouple this first electrode from the capacitor plate or finger.

FIG. 7 illustrates a cross-sectional view of a microelectronic device having a package substrate with an integrated piezoelectrically actuated tunable capacitor in accordance with an alternative embodiment. The microelectronic device 700 includes a package substrate 750 having a piezoelectrically actuated tunable capacitor 780, dielectric material 702 (e.g., organic material, low temperature co-fired ceramic materials, liquid crystal polymers, etc.) that includes organic layers, and different levels of conductive layers and connections. The capacitor 780 includes conductive electrodes 720 and 781 of the piezoelectric actuator 784, a piezoelectric layer 782, and conductive layers 786 and 787. The capacitor 780 is formed in the organic package substrate 750 and electrically routed with the standard conductive layers and connections in the package substrate. The conductive layers 786 and 787 (e.g., members 786 and 787) are shaped like a plate in FIG. 7. The dielectric layer 725 electrically isolates the electrode 781 from the conductive layer 786. The connection 783 (e.g., anchor 783) provides mechanical support for one of the electrodes of the piezoelectric actuator 784. The members 786 and 787 are separated by a gap d of a cavity 785 in an unactuated state and this gap d changes during an actuated state. This architecture utilizes a parallel plate capacitor and out of plane actuation. In this architecture, the capacitor 780 includes two members (e.g., plates) separated by a gap d in the vertical direction. The members can be beams, cantilevers, or membranes of any shape (e.g., rectangular, square, circle, triangle, etc) or combinations of those shapes. The members can be anchored on one or both sides.

Although piezoelectric films typically require very high crystallization temperatures that are not compatible with organic substrates, the present design utilizes a process that allows the deposition and crystallization of high quality piezoelectric films without heating the organic layers to temperatures that would cause their degradation. This novel process enables the integration of piezoelectric films directly in the package substrate.

The package substrates and capacitors can have different thicknesses, length, and width dimensions in comparison to those disclosed and illustrated herein. In another embodiment, any of the devices or components can be coupled to each other.

Other embodiments might include tunable voltage controlled oscillators and phase shifters. Other embodiments might include reconfigurable RF matching networks. Other embodiments might include the creation of reconfigurable diplexers/triplexers etc. Diplexers are typically used with radio receivers or transmitters on different, widely separated, frequency bands.

It will be appreciated that, in a system on a chip embodiment, the die may include a processor, memory, communications circuitry and the like. Though a single die is illustrated, there may be none, one or several dies included in the same region of the wafer.

In one embodiment, the microelectronic device may be a crystalline substrate formed using a bulk silicon or a silicon-on-insulator substructure. In other implementations, the microelectronics device may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the scope of embodiments of the present invention.

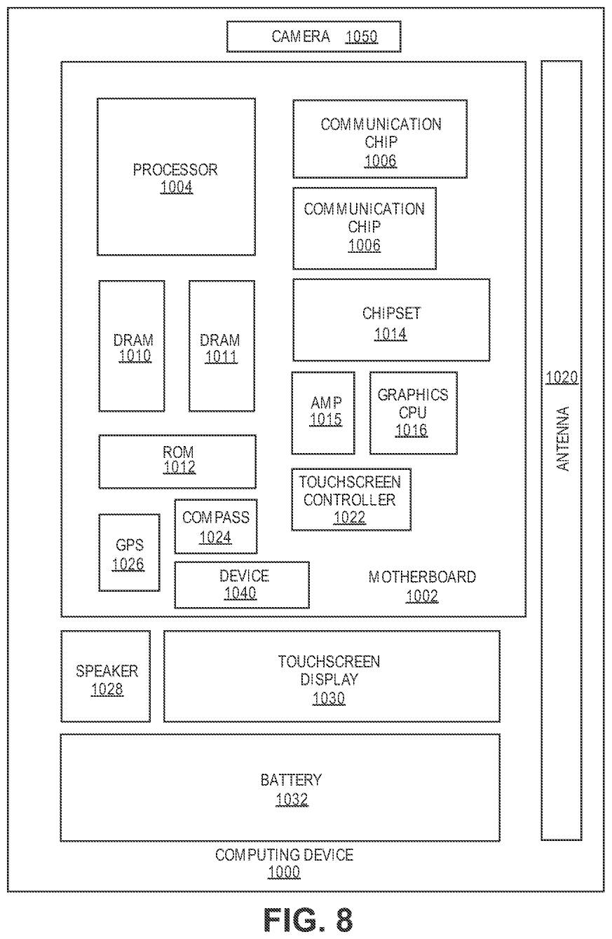

FIG. 8 illustrates a computing device 1000 in accordance with one embodiment. The computing device 1000 houses a board 1002. The board (e.g., motherboard, printed circuit board, etc.) may include a number of components, including but not limited to at least one processor 1004 and at least one communication chip 1006. The at least one processor 1004 is physically and electrically coupled to the board 1002. In some implementations, the at least one communication chip 1006 is also physically and electrically coupled to the board 1002. In further implementations, the communication chip 1006 (e.g., microelectronic device 100, 200, 300, 400, 500, 600, 700, etc.) is part of the processor 1004.

Depending on its applications, computing device 1000 may include other components that may or may not be physically and electrically coupled to the board 1002. These other components include, but are not limited to, volatile memory (e.g., DRAM 1010, 1011), non-volatile memory (e.g., ROM 1012), flash memory, a graphics processor 1016, a digital signal processor, a crypto processor, a chipset 1014, an antenna unit 1020, a display, a touchscreen display 1030, a touchscreen controller 1022, a battery 1032, an audio codec, a video codec, a power amplifier 1015, a global positioning system (GPS) device 1026, a compass 1024, a gyroscope, a speaker, a camera 1050, and a mass storage device (such as hard disk drive, compact disk (CD), digital versatile disk (DVD), and so forth).

The communication chip 1006 enables wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), WiGig, IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1000 may include a plurality of communication chips 1006. For instance, a first communication chip 1006 may be dedicated to shorter range wireless communications such as Wi-Fi, WiGig, and Bluetooth and a second communication chip 1006 may be dedicated to longer range wireless communications such as GPS, EDGE, GPRS, CDMA, WiMAX, LTE, Ev-DO, 5G, and others.

The at least one processor 1004 of the computing device 1000 includes an integrated circuit die packaged within the at least one processor 1004. In some embodiments of the invention, the processor package includes one or more devices, such as microelectronic devices (e.g., microelectronic device 100, 200, 300, 400, 500, 600, 700, etc.) having a package integrated tunable capacitor in accordance with implementations of embodiments of the invention. The term “processor” may refer to any device or portion of a device that processes electronic data from registers and/or memory to transform that electronic data into other electronic data that may be stored in registers and/or memory.

The communication chip 1006 also includes an integrated circuit die packaged within the communication chip 1006. In accordance with another implementation of embodiments of the invention, the communication chip package includes one or more microelectronic devices (e.g., microelectronic device 100, 200, 300, 400, 500, 600, 700, etc.) having package-integrated tunable capacitors.

The following examples pertain to further embodiments. Example 1 is a microelectronic device that includes a plurality of organic dielectric layers and a piezoelectrically actuated tunable capacitor having a variable capacitance formed in-situ with at least one organic dielectric layer of the plurality of organic dielectric layers. A piezoelectric actuator of the tunable capacitor includes first and second conductive electrodes and a piezoelectric layer that is positioned between the first and second conductive electrodes.

In example 2, the subject matter of example 1 can optionally include a conductive layer formed above a cavity of the microelectronic device. The conductive layer includes a first region that overlaps a second region of the first electrode.

In example 3, the subject matter of any of examples 1-2 can optionally include the tunable capacitor that operates with piezoelectric actuation based on applying a voltage across the first and second electrodes to cause a change in the overlap of the first and second regions to change the variable capacitance of the tunable capacitor.

In example 4, the subject matter of any of examples 1-3 can optionally include applying a voltage across the first and second electrodes to cause actuation of at least one of the first and second regions to cause a change in the overlap of the first and second regions to change the variable capacitance of the tunable capacitor.

In example 5, the subject matter of any of examples 1-4 can optionally include the first and second regions each comprising at least one of beams, cantilevers, and membranes of any shape.

In example 6, the subject matter of any of examples 1-5 can optionally include the first and second regions each comprising at least one of beams, cantilevers, and membranes that are formed above the cavity.

In example 7, the subject matter of any of examples 1-3 can optionally include the piezoelectric layer comprises at least one of lead zirconate titanate (PZT), sodium potassium niobate (KNN), and zinc oxide.

In example 8, the subject matter of any of examples 1-7 can optionally include the tunable capacitance of the piezoelectrically actuated capacitor that enables a reconfigurable microelectronic device.

In example 9, the subject matter of any of examples 1-8 can optionally include the first and second regions overlapping each other with an interdigitated configuration.

Example 10 is a microelectronic device comprising a plurality of organic dielectric layers and a tunable capacitor having a variable capacitance based on piezoelectric actuation. The tunable capacitor is integrated with at least one organic dielectric layer of the plurality of organic dielectric layers and a piezoelectric actuator of the tunable capacitor includes first and second conductive electrodes and a piezoelectric layer that is positioned between the first and second conductive electrodes.

In example 11, the subject matter of example 10 can optionally include a conductive layer formed near a bottom of a cavity and a gap of the cavity formed between a first member of the conductive layer and a second member of the first conductive electrode.

In example 12, the subject matter of any of examples 10-11 can optionally include the tunable capacitor that operates with piezoelectric actuation based on applying a voltage across the first and second electrodes to cause actuation of the second member to cause a change in the gap that causes the variable capacitance of the tunable capacitor to change.

In example 13, the subject matter of any of examples 10-12 can optionally include the first and second members that each comprise at least one of beams, cantilevers, and membranes of any shape.

In example 14, the subject matter of any of examples 10-13 can optionally include a conductive layer formed above a cavity and a gap formed between a first member of the conductive layer and a second member of the first conductive electrode.

In example 15, the subject matter of any of examples 10-14 can optionally include the piezoelectric layer that comprises at least one of lead zirconate titanate (PZT), sodium potassium niobate (KNN), and zinc oxide.

In example 16, the subject matter of any of examples 10-15 can optionally include a dielectric layer coupled to the first electrode, a first conductive member coupled to the dielectric layer, a second conductive member, and a gap of a cavity formed between the first and second members.

In example 17, the subject matter of any of examples 10-16 can optionally include the tunable capacitor that operates with piezoelectric actuation based on applying a voltage across the first and second electrodes to cause actuation of the first conductive member to cause a change in the gap that causes the variable capacitance of the tunable capacitor to change.

Example 18 is a computing device comprising an integrated circuit die and a package substrate coupled to the integrated circuit die. The package substrate includes a piezoelectrically actuated tunable capacitor having a variable capacitance formed in-situ with at least one organic dielectric layer of the package substrate and a piezoelectric actuator of the tunable capacitor includes first and second conductive electrodes and a piezoelectric layer that is positioned between the first and second conductive electrodes.

In example 19, the subject matter of example 18 can optionally include a conductive layer that is formed above a cavity of the microelectronic device. The conductive layer includes a first region that overlaps a second region of the first electrode.

In example 20, the subject matter of any of examples 18-19 can optionally include the tunable capacitor that operates with piezoelectric actuation based on applying a voltage across the first and second electrodes to cause a change in the overlap of the first and second regions to change the variable capacitance of the tunable capacitor.

In example 21, the subject matter of any of examples 18-20 can optionally include a printed circuit board coupled to the package substrate.

What is claimed is:

1. A microelectronic device comprising:
a plurality of organic dielectric layers; and
a piezoelectrically actuated tunable capacitor having a variable capacitance formed in-situ with at least one organic dielectric layer of the plurality of organic dielectric layers, and a piezoelectric actuator of the tunable capacitor includes first and second conductive electrodes and a piezoelectric layer that is positioned between the first and second conductive electrodes.

2. The microelectronic device of claim 1, further comprising:
a conductive layer formed above a cavity of the microelectronic device, the conductive layer includes a first region that overlaps a second region of the first electrode.

3. The microelectronic device of claim 2, wherein the tunable capacitor operates with piezoelectric actuation based on applying a voltage across the first and second electrodes to cause a change in the overlap of the first and second regions to change the variable capacitance of the tunable capacitor.

4. The microelectronic device of claim 3, wherein applying a voltage across the first and second electrodes causes actuation of the second region of the first electrode to cause a change in the overlap of the first and second regions to change the variable capacitance of the tunable capacitor.

5. The microelectronic device of claim 4, wherein the first and second regions each comprise at least one of beams, cantilevers, and membranes of any shape.

6. The microelectronic device of claim 4, wherein the first and second regions each comprise at least one of beams, cantilevers, and membranes that are formed above the cavity.

7. The microelectronic device of claim 5, wherein the piezoelectric layer comprises at least one of lead zirconate titanate (PZT), sodium potassium niobate (KNN), and zinc oxide.

8. The microelectronic device of claim 1, wherein the tunable capacitance of the piezoelectrically actuated capacitor enables a reconfigurable microelectronic device.

9. The microelectronic device of claim 1, wherein the first and second regions overlap each other with an interdigitated configuration.

10. A microelectronic device comprising:
a plurality of organic dielectric layers; and
a tunable capacitor having a variable capacitance based on piezoelectric actuation, wherein the tunable capacitor is integrated with at least one organic dielectric layer of the plurality of organic dielectric layers and a piezoelectric actuator of the tunable capacitor includes first and second conductive electrodes and a piezoelectric layer that is positioned between the first and second conductive electrodes.

11. The microelectronic device of claim 10, further comprising:
a conductive layer formed near a bottom of a cavity; and
a gap of the cavity formed between a first member of the conductive layer and a second member of the first conductive electrode.

12. The microelectronic device of claim 11, wherein the tunable capacitor operates with piezoelectric actuation based on applying a voltage across the first and second electrodes to cause actuation of the second member to cause a change in the gap that causes the variable capacitance of the tunable capacitor to change.

13. The microelectronic device of claim 10, wherein the first and second members each comprise at least one of beams, cantilevers, and membranes of any shape.

14. The microelectronic device of claim 10, further comprising:
a conductive layer formed above a cavity; and
a gap formed between a first member of the conductive layer and a second member of the first conductive electrode.

15. The microelectronic device of claim 10, wherein the piezoelectric layer comprises at least one of lead zirconate titanate (PZT), sodium potassium niobate (KNN), and zinc oxide.

16. The microelectronic device of claim 10, further comprising:
a dielectric layer coupled to the first electrode;
a first conductive member coupled to the dielectric layer;
a second conductive member; and
a gap of a cavity formed between the first and second members.

17. The microelectronic device of claim 16, wherein the tunable capacitor operates with piezoelectric actuation based on applying a voltage across the first and second electrodes to cause actuation of the first conductive member to cause a change in the gap that causes the variable capacitance of the tunable capacitor to change.

18. A computing device comprising:
an integrated circuit die; and
a package substrate coupled to the integrated circuit die, the package substrate includes a piezoelectrically actuated tunable capacitor having a variable capacitance formed in-situ with at least one organic dielectric layer of the package substrate, and a piezoelectric actuator of the tunable capacitor includes first and second conductive electrodes and a piezoelectric layer that is positioned between the first and second conductive electrodes.

19. The computing device of claim 18, further comprising:
a conductive layer formed above a cavity of the microelectronic device, the conductive layer includes a first region that overlaps a second region of the first electrode.

20. The computing device of claim 19, wherein the tunable capacitor operates with piezoelectric actuation based on applying a voltage across the first and second electrodes to cause a change in the overlap of the first and second regions to change the variable capacitance of the tunable capacitor.

21. The computing device of claim 17, further comprising:
a printed circuit board coupled to the package substrate.
